(19) United States
(12) Patent Application Publication
(10) Pub. No.: US 2007/0152219 A1
(43) Pub. Date: Jul. 5, 2007

(54) Thin film transistor array substrate and manufacturing method thereof

(75) Inventor: Byoung Ho Lim, Gyeongsangbuk-do (KR)

Correspondence Address: SEYFARTH SHAW, LLP, 815 CONNECTICUT AVENUE, N.W., SUITE 500, WASHINGTON, DC, 20006, US

(73) Assignee: LG.PHILIPS LCD CO., LTD., Seoul (KR)

(21) Appl. No.: 11/638,513

(22) Filed: Dec. 14, 2006

(30) Foreign Application Priority Data
Dec. 30, 2005 (KR) 10-2005-0135020

(51) Int. Cl. H01L 29/04

(52) U.S. Cl. 257/59; 257/72; 438/151; 257/E29.117

(57) ABSTRACT

A thin film transistor array substrate includes a gate line and a data line intersecting each other on a substrate with a gate insulating film therebetween, a thin film transistor at an intersection of the gate line and the data line, the thin film transistor including a gate electrode electrically connected to the gate line, a semiconductor pattern overlapping the gate electrode with the gate insulating film therebetween, and a source electrode and a drain electrode above the semiconductor pattern, and a pixel electrode contacting the drain electrode of the thin film transistor, the drain electrode substantially completely overlapping at least one of the gate electrode and the gate line.

The present invention claims the benefit of Korean Patent Application No. P05-0135020 filed in Korea on Dec. 30, 2005, which is hereby incorporated by reference in its entirety.

### BACKGROUND OF THE INVENTION

1. Field of the Invention

The invention relates to a flat panel display device, and more particularly, to a thin film transistor array substrate and a manufacturing method thereof for a liquid crystal display device. Although embodiments of the invention is suitable for a wide scope of applications, it is particularly suitable for avoiding leakage current generation in a thin film transistor array substrate, to thereby improve the display quality.

2. Discussion of the Related Art

A liquid crystal display (“LCD”) device controls light transmittance of a liquid crystal material using an electric field, to thereby display a picture. In general, an LCD device includes a liquid crystal display panel having liquid crystal cells arranged in a matrix type, and a driving circuit for driving the liquid crystal display panel. In addition, the liquid crystal display panel includes two substrates opposed to each other, a liquid crystal injected between the two substrates, and a spacer for maintaining a cell gap between the two substrates. The substrates commonly are referred to as a thin film transistor array substrate and a color filter array substrate, respectively.

The thin film transistor array substrate includes gate lines, data lines, thin film transistors as switching devices for each intersection between the gate lines and the data lines, pixel electrodes in each liquid crystal cell and connected to the thin film transistor, and alignment films coated thereon. The gate lines and the data lines receive signals from the driving circuit via a pad portion. The thin film transistor applies a pixel signal applied to the data line to the pixel electrode in response to a scanning signal applied to the gate line.

In addition, the color filter array substrate includes color filters for each liquid crystal cell, black matrices for dividing the color filters and reflecting an external light, common electrodes for commonly applying reference voltages to the liquid crystal cells, and an alignment film coated thereon. The thin film transistor array substrate and the color filter array substrate are manufactured separately, and the liquid crystal display panel is formed by attaching the substrates opposing each other with a cell gap therebetween and then injecting a liquid crystal material between the attached substrates.

FIG. 1 is a planar schematic diagram illustrating a portion of a thin film transistor array substrate according to the related art, and FIG. 2 is a sectional schematic diagram of the thin film transistor array substrate along I-I′ shown in FIG. 1. In FIGS. 1 and 2, a thin film transistor array substrate includes a gate line 2 and a data line 4 on a lower substrate 42. The gate and data lines 2 and 4 intersect each other with a gate insulating film 44 therebetween, and a thin film transistor 6 is provided at each intersection. In addition, a pixel electrode 18 is provided at a cell area defined by the intersection of the gate and data lines 2 and 4. Further, the thin film transistor array substrate includes a storage capacitor 20 provided at an overlapped portion between the pixel electrode 18 and the pre-stage gate line 2.

The thin film transistor 6 includes a gate electrode 8 connected to the gate line 2, a source electrode 10 connected to the data line 4, a drain electrode 12 connected to the pixel electrode 18, and an active layer 14 overlapping with the gate electrode 8 and defining a channel portion 51 between the source electrode 10 and the drain electrode 12. The gate electrode 8 is a portion protruding from the gate line 2, and the active layer 14 is provided to overlap the data line 4, the source electrode 10, and the drain electrode 12. The channel portion 51 is a “U” type channel provided between two source electrodes 10 and one drain electrode 12. An ohmic contact layer 47 is formed on the active layer 14 and provides an ohmic contact with the data line 4, the source electrode 10, and the drain electrode 12. Herein, the active layer 14 and the ohmic contact layer 47 are referred to as a semiconductor pattern 48.

The thin film transistor 6 allows a pixel voltage signal applied to the data line 4 to be charged into the pixel electrode 18 and kept in response to a gate signal applied to the gate line 2. In addition, the pixel electrode 18 is connected, via a contact hole 16 passing through a protective film 50, to the drain electrode 12 of the thin film transistor 6. The pixel electrode 18 generates a potential difference with respect to a common electrode provided at an upper substrate (not shown) by the charged pixel voltage signal. This potential difference rotates a liquid crystal (not shown) positioned between the thin film transistor array substrate and the upper substrate (not shown) due to a dielectric anisotropy and transmits light inputted, via the pixel electrode 18, from a light source (not shown) toward the upper substrate (not shown).

The gate line 2 is electrically connected to a gate driver (not shown) to be supplied with a gate voltage from the gate driver (not shown), and the data line 4 is electrically connected to a data driver (not shown) to be supplied with a data voltage from the data driver (not shown).

A thin film transistor array substrate having such a configuration is formed by a four-mask process. First, a gate pattern including the gate line 2 and the gate electrode 8 is formed by a first mask process. A source/drain pattern including the semiconductor pattern 48, the source electrode 10, a drain electrode 112 and a data line 104, and the thin film transistor 6 are formed by a second mask process. The protective film 50 having the contact hole 16 for exposing the drain electrode 12 of the thin film transistor 6 is formed by a third mask process. The pixel electrode 18 contacted, via the contact hole 16, with the drain electrode 12 is formed by a fourth mask process.

In such a thin film transistor array substrate according to the related art, the semiconductor pattern 48 of a lower portion of the drain electrode 12 of the thin film transistor 6 is activated by a backlight light, such that a leakage current is generated and the leak current flows from the drain electrode 12 into the source electrode 10. Accordingly, a pixel voltage of the pixel electrode 18 is not uniformly maintained, thereby deteriorating the display quality.

FIG. 3 is a schematic diagram illustrating a generation of a leakage current in the thin film transistor array substrate shown in FIG. 1. As shown in FIG. 3, the semiconductor pattern 48 and the source/drain pattern are formed by one mask process, and the semiconductor pattern 48 is activated by a backlight light due to semiconductor characteristics. Accordingly, as light generated from a backlight light is supplied to the thin film transistor array substrate, the semiconductor pattern 48 including a semiconductor pattern portion B of a lower portion of the drain electrode 12, is activated. When the semiconductor pattern portion B of a lower portion of the drain electrode 12 is activated, a leakage current is generated and flows from the pixel electrode 18, via the drain electrode 12, into the source electrode 10 during a holding time after a scanning period. Accordingly, a pixel voltage charged into the pixel electrode 18 during a scanning period is not maintained during a holding time, thereby deteriorating panel brightness and generating a cross talk. Thus, a display quality of the panel is deteriorated.

### SUMMARY OF THE INVENTION

Accordingly, embodiments of the invention is directed to a thin film transistor array substrate and a manufacturing method thereof that substantially obviate one or more of the problems due to limitations and disadvantages of the related art.

An object of embodiments of the invention is to provide a thin film transistor array substrate and a manufacturing method thereof that avoid leakage current generation in a thin film transistor array substrate, to thereby improve the display quality.

Another object of embodiments of the invention is to provide a thin film transistor array substrate and a manufacturing method thereof that have an increased aperture ratio.

Another object of embodiments of the invention is to provide a thin film transistor array substrate and a manufacturing method thereof that have an improved contact between a source electrode of a thin film transistor and a pixel electrode.

Another object of embodiments of the invention is to provide a thin film transistor array substrate and a manufacturing method thereof that have a simplified structure/process.

Additional features and advantages of embodiments of the invention will be set forth in the description which follows, and in part will be apparent from the description, or may be learned by practice of embodiments of the invention. The objectives and other advantages of the embodiments of the invention will be realized and attained by the structure particularly pointed out in the written description and claims hereof as well as the appended drawings.

To achieve these and other advantages and in accordance with the purpose of embodiments of the invention, as embodied and broadly described, a thin film transistor array substrate includes a gate line and a data line intersecting each other on a substrate with a gate insulating film therebetween, a thin film transistor at an intersection of the gate line and the data line, the thin film transistor including a gate electrode electrically connected to the gate line, a semiconductor pattern overlapping the gate electrode with the gate insulating film therebetween, and a source electrode and a drain electrode above the semiconductor pattern, and a pixel electrode contacting the drain electrode of the thin film transistor, the drain electrode substantially completely overlapping at least one of the gate electrode and the gate line.

In another aspect, a method of fabricating a thin film transistor array substrate include forming a gate pattern on a substrate, the gate pattern including a gate line and a gate electrode electrically connected to the gate line, forming a gate insulating film covering the gate pattern, forming a semiconductor pattern and a source/drain pattern on the gate insulating film, the source/drain pattern including a data line intersecting the gate line, a source electrode electrically connected to the data line, and a drain electrode opposed to the source electrode, and forming a pixel electrode contacted the drain electrode, the drain electrode substantially completely overlapping at least one of the gate electrode and the gate line.

In yet another aspect, a thin film transistor array substrate includes a gate line and a data line intersecting each other on a substrate, a thin film transistor provided at each intersection between the data line and the gate line, and a pixel electrode electrically connected to the thin film transistor, the thin film transistor being composed of the gate line, a source electrode electrically connected to the data line, a drain electrode opposed to the source electrode, and a semiconductor pattern, wherein the gate line shields light from being incident onto the semiconductor pattern.

It is to be understood that both the foregoing general description and the following detailed description are exemplary and explanatory and are intended to provide further explanation of embodiments of the invention as claimed.

### BRIEF DESCRIPTION OF THE DRAWINGS

The accompanying drawings, which are included to provide a further understanding of embodiments of the invention and are incorporated in and constitute a part of this specification, illustrate embodiments of the invention and together with the description serve to explain the principles of embodiments of the invention.

FIG. 1 is a planar schematic diagram illustrating a portion of a thin film transistor array substrate according to the related art;

FIG. 2 is a sectional schematic diagram of the thin film transistor array substrate along I-I′ shown in FIG. 1;

FIG. 3 is a schematic diagram illustrating a generation of a leakage current in the thin film transistor array substrate shown in FIG. 1;

FIG. 4 is a planar schematic diagram illustrating a portion of a thin film transistor array substrate according to an embodiment of the invention;

FIG. 5 is a sectional schematic diagram of the thin film transistor array substrate along II-II shown in FIG. 4;

FIG. 6 is a schematic diagram illustrating a gate electrode shielding a backlight light incident into a semiconductor pattern in a thin film transistor array substrate according to an embodiment of the invention;

FIGS. 7A to 7D are sectional schematic diagrams illustrating a method of manufacturing a thin film transistor array substrate according to an embodiment of the invention;

FIG. 8 is a planar schematic diagram illustrating a portion of a thin film transistor array substrate according to another embodiment of the invention;

FIG. 9 is a sectional schematic diagram of the thin film transistor array substrate along II-II′ shown in FIG. 8;

FIG. 10 is a planar schematic diagram illustrating a portion of a thin film transistor array substrate according to yet another embodiment of the invention; and

FIGS. 11A and 11B are sectional schematic diagrams illustrating a method of manufacturing a thin film transistor array substrate according to another embodiment of the invention.

### DETAILED DESCRIPTION OF THE PREFERRED EMBODIMENTS

Reference will now be made in detail to the preferred embodiments of the invention, examples of which are illustrated in the accompanying drawings.

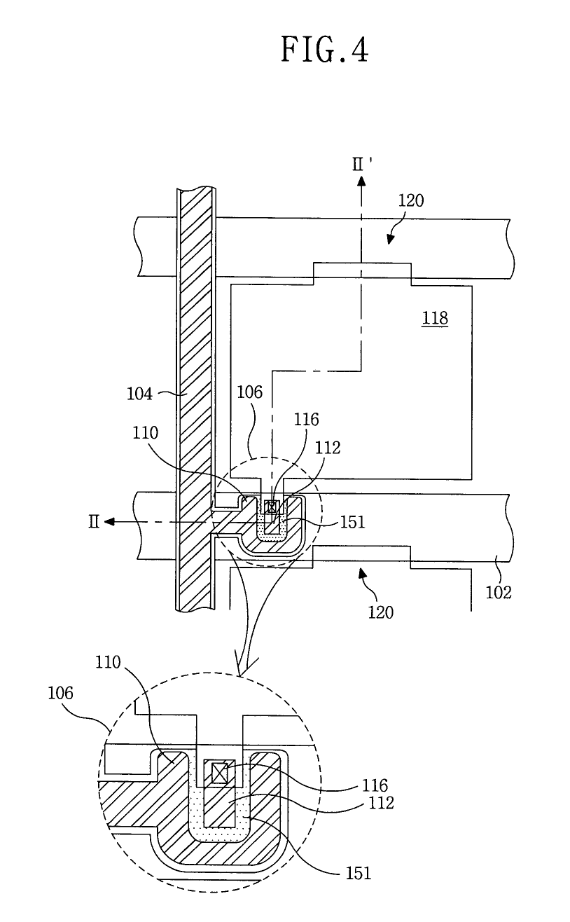

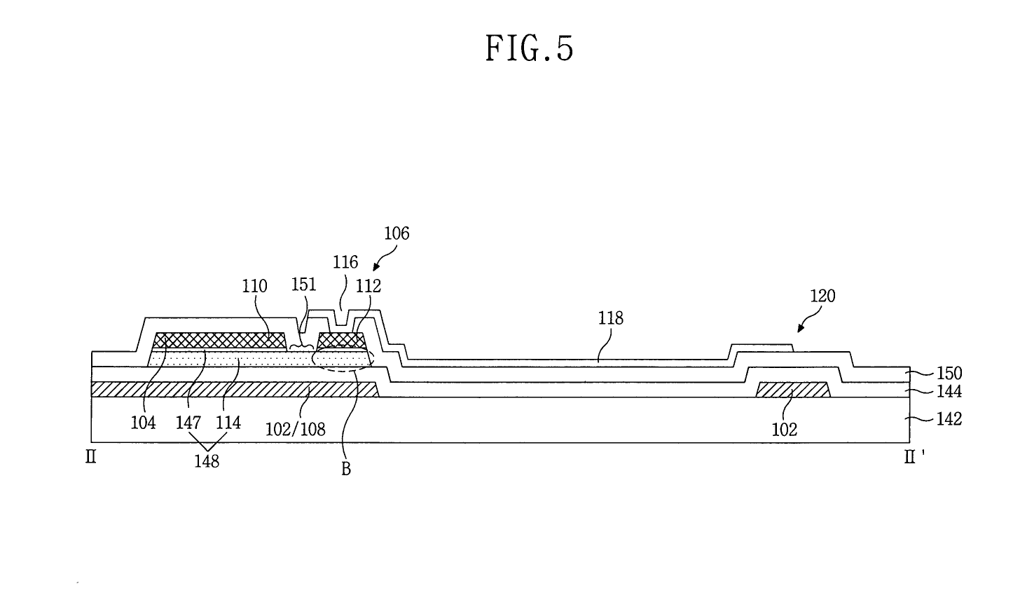

FIG. 4 is a planar schematic diagram illustrating a portion of a thin film transistor array substrate according to an embodiment of the invention, and FIG. 5 is a sectional schematic diagram of the thin film transistor array substrate along II-II′ shown in FIG. 4. In FIGS. 4 and 5, a thin film transistor array substrate includes a gate line 102 and a data line 104 on a lower substrate 142. The gate and data lines 102 and 104 intersect each other with a gate insulating film 144 therebetween, and a thin film transistor 106 is provided at each intersection of the gate and data lines 102 and 104. In addition, a pixel electrode 118 is provided at a cell area defined by the intersection of the gate and data lines 102 and 104. Further, the thin film transistor array substrate includes a storage capacitor 120 provided at an overlapped portion between the pixel electrode 118 and the pre-stage gate line 102.

The thin film transistor 106 includes a gate electrode 108, a source electrode 110 connected to the data line 104, a drain electrode 112 connected to the pixel electrode 118, and an active layer 114 overlapping with the gate electrode 108 and defining a channel portion 151 between the source electrode 110 and the drain electrode 112. The active layer 114 is provided to overlap the data line 104, the source electrode 110, and the drain electrode 112. The channel portion 151 is a “U” type channel provided between two source electrodes 110 and one drain electrode 112. An ohmic contact layer 147 is formed on the active layer 114 and provides an ohmic contact with the data line 104, the source electrode 110, and the drain electrode 112. Herein, the active layer 114 and the ohmic contact layer 147 are alternatively referred to as a semiconductor pattern 148.

The gate line 102 may be formed to have a wider line width in comparison to the related art. As shown in FIG. 4, the gate electrode 108 may be a non-protruding portion of the gate line 102, and the pixel electrode 118 may include a protruding portion extending above the drain electrode 112 and the gate line 102. In addition, the source electrode 110 is a protruding portion from the data line 104 and may be entirely above the gate line 102. Also, the source electrode 110 is extended from the data line 104 to be opposed to the drain electrode 112, and the source electrode 110 may be branched into two directions. The drain electrode 112 may be positioned entirely above the gate line 102. Accordingly, the channel portion 151 of the thin film transistor 106 is entirely above the gate line 102, to thereby increasing aperture ratio of the cell area.

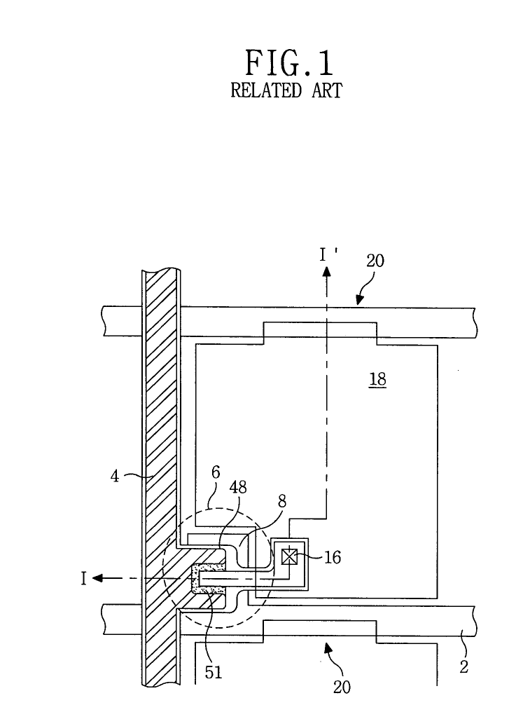

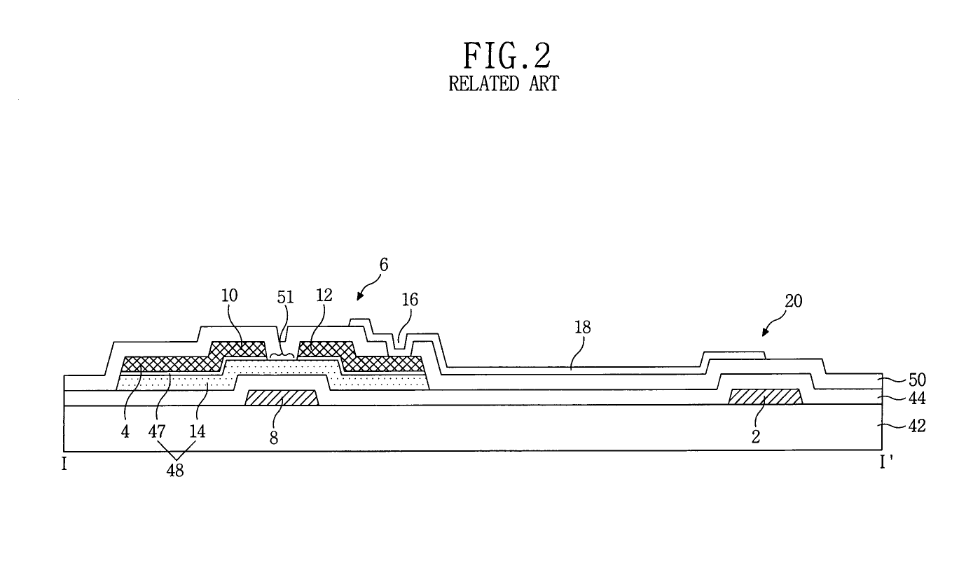

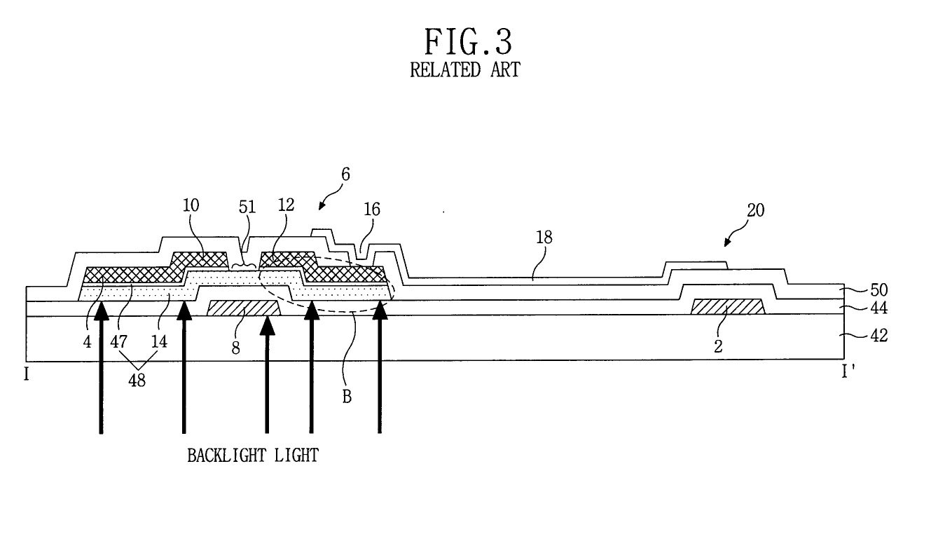

Although not shown, the gate electrode 108 alternatively may include a protruding portion from the gate line 102, the source electrode 110 alternatively may not be entirely above the gate line 102, and the channel portion 151 alternatively may not be above the gate line 102, similar to the configuration shown in FIG. 1. In addition or alternatively, the gate electrode 108 may be comprised of a non-protruding portion of the gate line 102 and a protruding portion from the gate line 102, such that a portion of the channel portion 151 is above the gate line 102.

The pixel electrode 118 is connected, via a contact hole 116 passing through a protective film 150, to the drain electrode 112 of the thin film transistor 106. The pixel electrode 118 generates a potential difference with respect to a common electrode provided at an upper substrate (not shown) by the charged pixel voltage signal.

The gate line 102 is electrically connected to a gate driver (not shown) to be supplied with a gate voltage from the gate driver (not shown), and the data line 104 is electrically connected to a data driver (not shown) to be supplied with a data voltage from the data driver (not shown).

The semiconductor pattern 148 includes a semiconductor pattern portion B, which is under the drain electrode 12. The semiconductor pattern portion B entirely overlaps the gate electrode 108. Accordingly, the gate electrode 108 prevents light from a backlight source from being incident to the semiconductor pattern portion B. Accordingly, the semiconductor pattern portion B is not activated by light from the backlight source and a leakage current is not generated, thereby preventing a deterioration of the display quality.

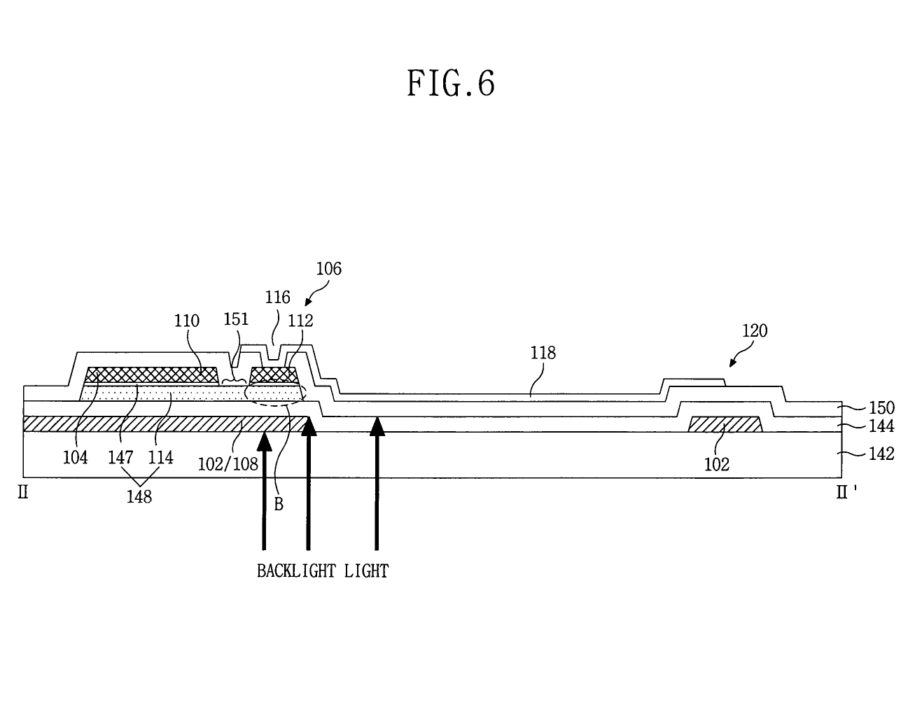

FIG. 6 is a schematic diagram illustrating a gate electrode shielding a backlight light incident into a semiconductor pattern in a thin film transistor array substrate according to an embodiment of the invention. As shown in FIG. 6, the drain electrode 112 and the semiconductor pattern portion B entirely overlap the gate electrode 108, and the semiconductor pattern portion B is exposed to the backlight light. As a result, the backlight light is shielded by the gate electrode 108 and is not to be incident onto the semiconductor pattern portion B. Accordingly, an activation of the semiconductor pattern 148 is prevented, and a leakage current is not generated. Thus, a display quality is improved.

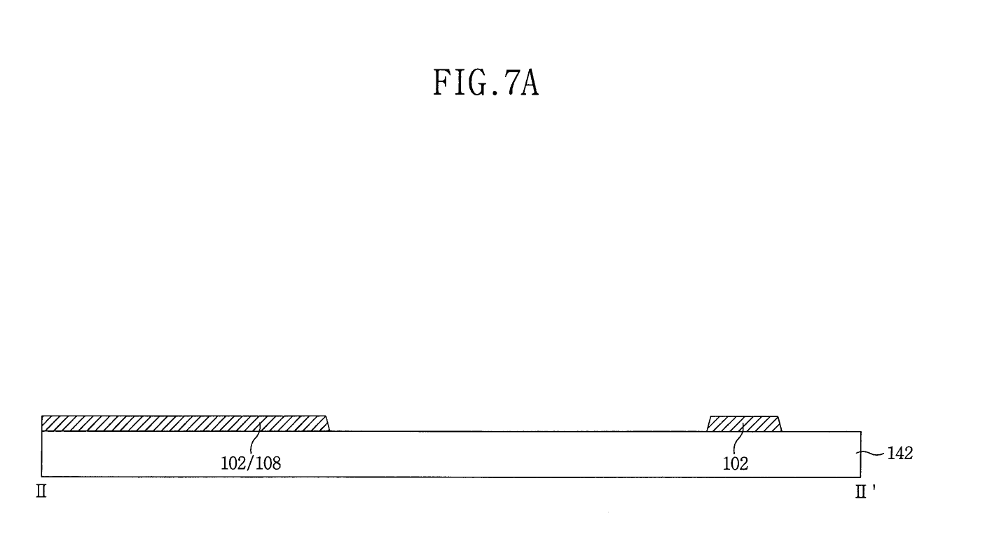

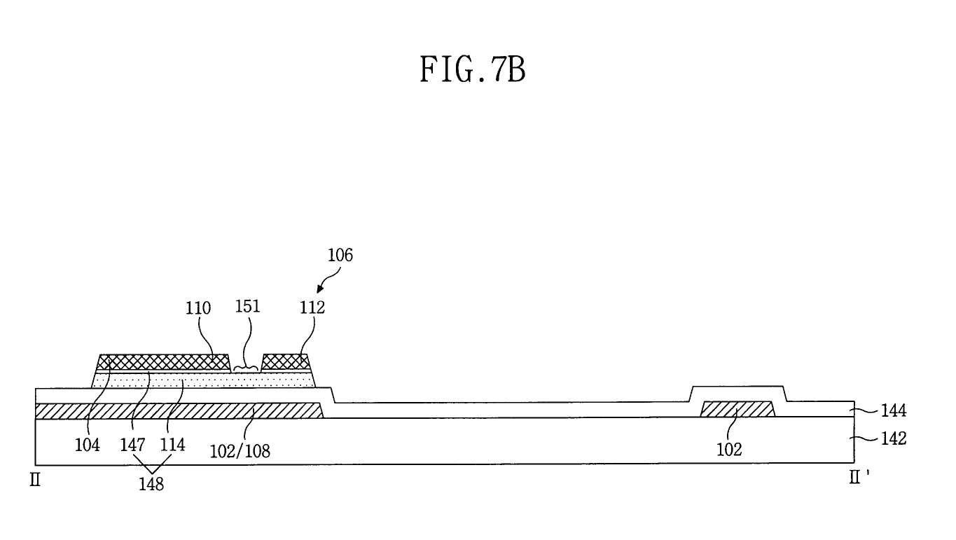

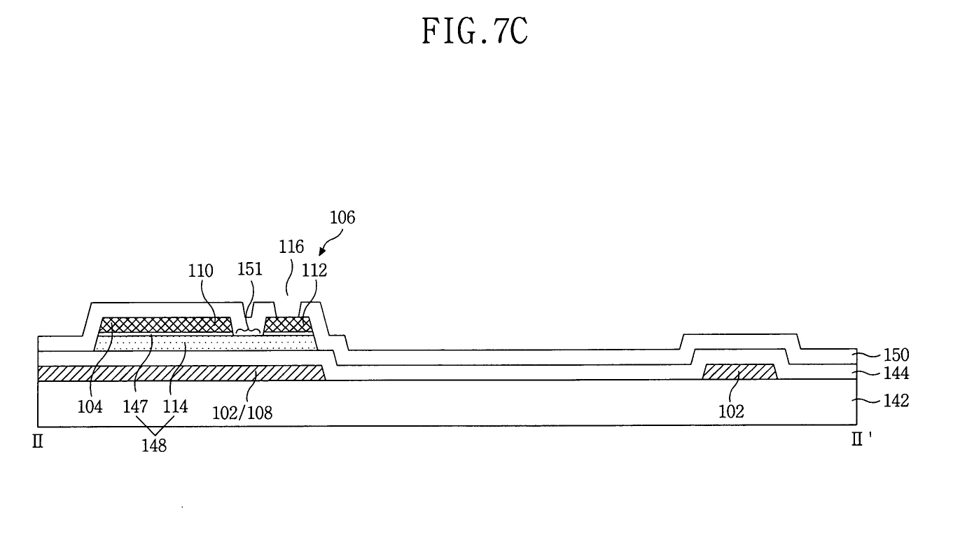

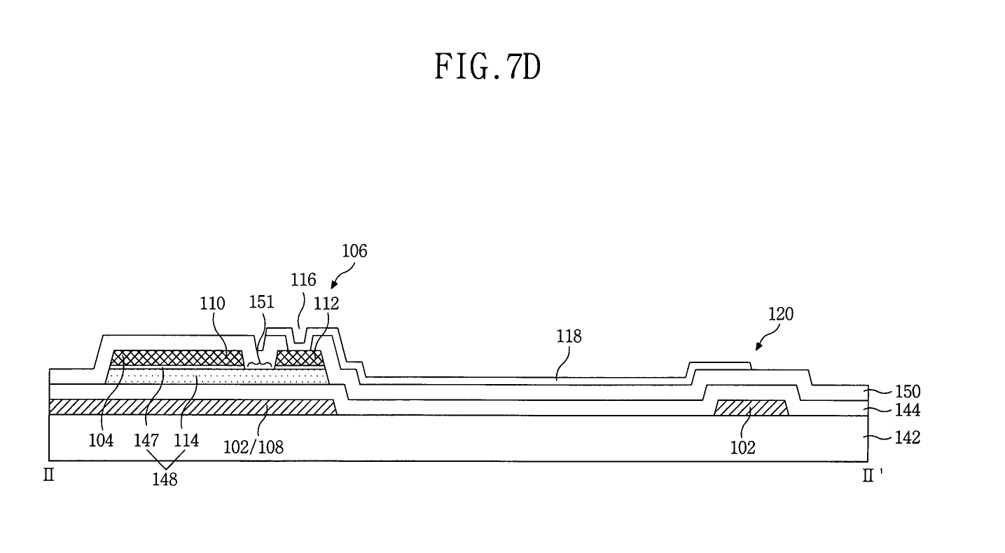

FIGS. 7A to 7D are sectional schematic diagrams illustrating a method of manufacturing a thin film transistor array substrate according to an embodiment of the invention. As shown in FIG. 7A, gate metal patterns including a gate line 102 and a gate electrode 108 are formed on a lower substrate 142. The gate metal patterns may be formed by depositing a gate metal layer on the lower substrate 142 and patterning the gate metal layer. The gate metal layer may be formed by a sputtering process, and may be patterned by a photolithography and etching process. The gate metal layer may include a single-layer or a multi-layer comprising of one of chrome (Cr), molybdenum (Mo) and an aluminum-group metal.

As shown in FIG. 7B, a gate insulating film 144, a semiconductor layer, and a source/drain metal layer are sequentially formed on the lower substrate 142. The semiconductor layer may include an amorphous silicon layer and an n+ amorphous silicon layer. The gate insulating film 144, the semiconductor layer and the source/drain metal layer may be formed by a plasma enhanced chemical vapor deposition (PECVD) process.

A photo-resist pattern (not shown) then is formed on the source/drain metal layer by the photolithography using a second mask. The second mask may include a diffractive exposure mask having a diffractive exposure portion at the channel portion of the thin film transistor, thereby allowing the photo-resist pattern at the channel portion to be etched more than other regions, such as source/drain patterns. Subsequently, the source/drain metal layer is patterned to form the source/drain patterns including a data line 104, a source electrode 110, and a drain electrode 112. The source/drain metal layer may be patterned by a wet etching process. Next, the semiconductor layer is patterned to form a semiconductor pattern 148 including an ohmic contact layer 147 and an active layer 114. The semiconductor layer may be patterned by a dry etching process.

Further, the photo-resist pattern at a channel portion 151 has a relatively lower height, and a lower height portion of the photo-resist pattern may be completely removed by an ashing process. Thereafter, the source/drain pattern and the ohmic contact layer 147 at the channel portion is further etched. The source/drain pattern and the ohmic contact layer 147 at the channel portion may be further etched by a dry etching process.

Thus, the active layer 114 of the channel portion 151 is exposed to disconnect the source electrode 110 from the drain electrode 112. In addition, the semiconductor pattern 148 positioned at the drain electrode 112 and at a lower portion of the drain electrode 112 are positioned to entirely overlap within an area of the gate electrode 108. Then, the photo-resist pattern remaining on the source/drain patterns is removed, for example, by a stripping process.

The gate insulating film 144 may include an inorganic insulating material, such as one of silicon oxide (SiOx) and silicon nitride (SiNx), and the source/drain metal layer may include one of molybdenum (Mo), titanium (Ti), tantalum (Ta), and a molybdenum alloy.

As shown in FIG. 7C, a protective film 150 is formed on the lower substrate 142 covering the gate insulating film 144, the source electrode 110, the drain electrode 112 and the channel portion 151. The protective film 150 may be formed by a PECVD process. The protective film 150 then is patterned to form a contact hole 116 exposing a region of the drain electrode 112. The protective film 150 may be patterned by a photolithography and etching processing using a third mask. The protective film 150 may include an inorganic insulating material, such as one of silicon oxide (SiOx), silicon nitride (SiNx) and silicon nitrification (SiOxNy), or an organic insulating material, such as one of an acrylic organic compound having a small dielectric constant, benzocyclobutene (BCB), and perfluorocyclobutane (PFCB).

As shown in FIG. 7D, a transparent electrode material is formed on the lower substrate 142 covering the protective film 150 and the exposed region of the drain electrode 112, and then is patterned to form a pixel electrode 118. The transparent electrode material may be formed by a sputtering process and may be patterned by a photolithography and etching process using a fourth mask. The pixel electrode 118 contacts, via the contact hole 116, the drain electrode 112, and a storage capacitor 120 is formed by the overlapping of the pixel electrode 118 and the gate line 102 with the gate insulating film 144 and the protective film 150 therebetween. The transparent electrode material may include one of indium-tin-oxide (ITO), tin-oxide (TO), and indium-zinc-oxide (IZO).

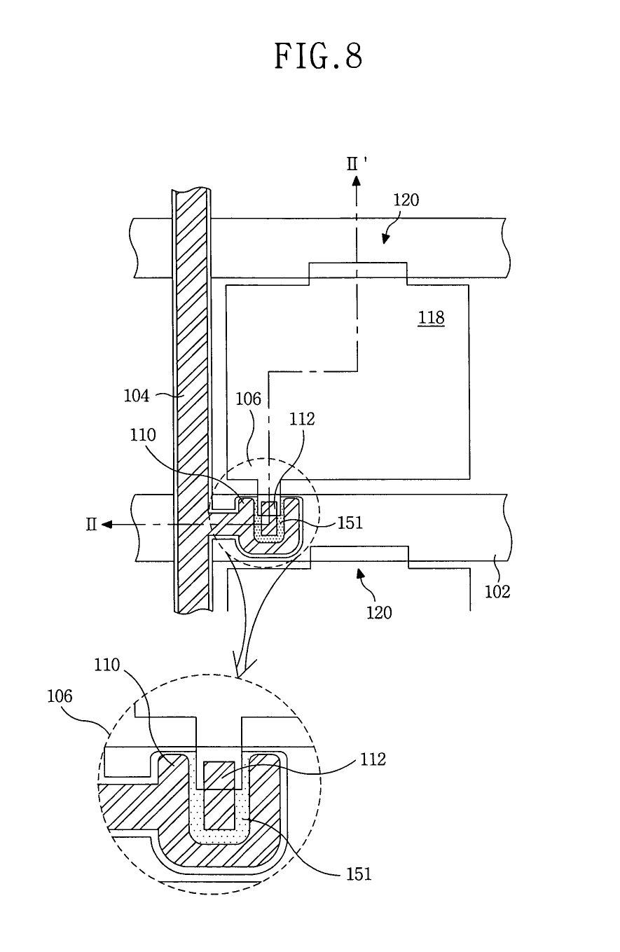

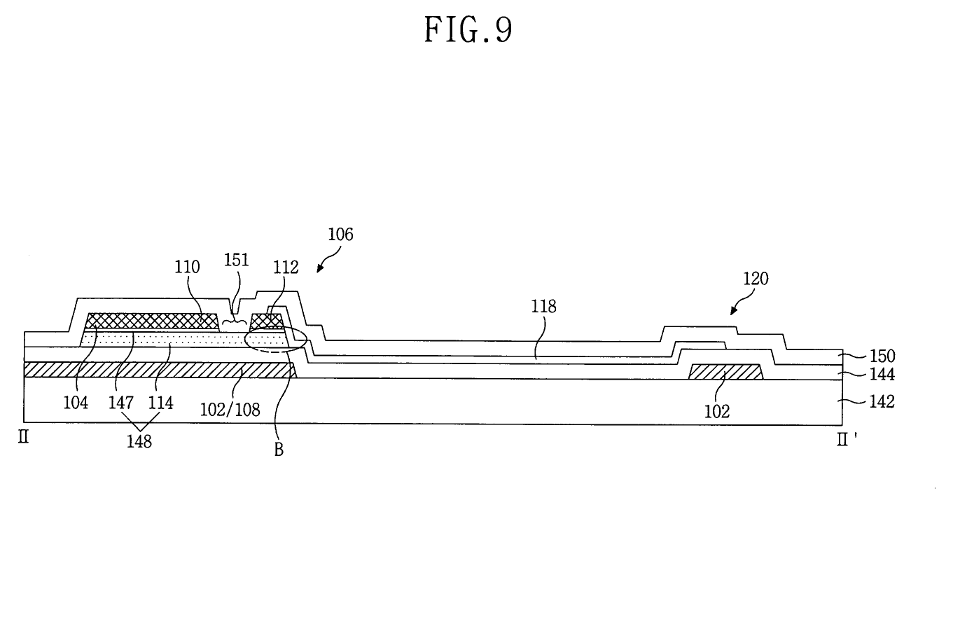

FIG. 8 is a planar schematic diagram illustrating a portion of a thin film transistor array substrate according to another embodiment of the invention, and FIG. 9 is a sectional schematic diagram of the thin film transistor array substrate along II-II′ shown in FIG. 8. As shown in FIGS. 8 and 9, a thin film transistor array substrate includes a thin film transistor 106 and a pixel electrode 118. The pixel electrode 118 is formed is directly on a source electrode 112 of the thin film transistor 106 and a gate insulating film 144. Thus, a portion of the pixel electrode 118 covers the drain electrode 112 without forming a separate contact hole in a protective film 150. For example, after the pixel electrode 118 is formed, the protective film 150 may be formed on a lower substrate 142. In addition, a storage capacitor 120 is formed by the overlapping of the pixel electrode 118 and the gate line 102 with only the gate insulating film 144 therebetween.

Accordingly, the pixel electrode 118 is contacted with the drain electrode 112 without a separate contact hole, to thereby widen a contact area between the pixel electrode 118 and the drain electrode 112. Thus, the drain electrode 112 may have a smaller surface area in comparison to the related art, and a contact defect problem between the drain electrode 112 and the pixel electrode 118 is prevented. In addition, the drain electrode 112 and a semiconductor pattern portion B entirely overlap the gate electrode 108, and the semiconductor pattern portion B is exposed to the backlight light. As a result, the backlight light is shielded by the gate electrode 108 and is not to be incident onto the semiconductor pattern portion B. Accordingly, an activation of the semiconductor pattern 148 is prevented, and a leakage current is not generated. Thus, a display quality is improved.

The thin film transistor array substrate shown in FIGS. 8 and 9 may be formed by a method similar to those shown in FIGS. 7A to 7D, with the pixel electrode 118 being formed before the protective film 150. In addition, a gate pad and a data pad may be formed by exposing a peripheral region of the gate line 102 and exposing a peripheral region of the data line 104 by a photolithography process and etching process using a mask.

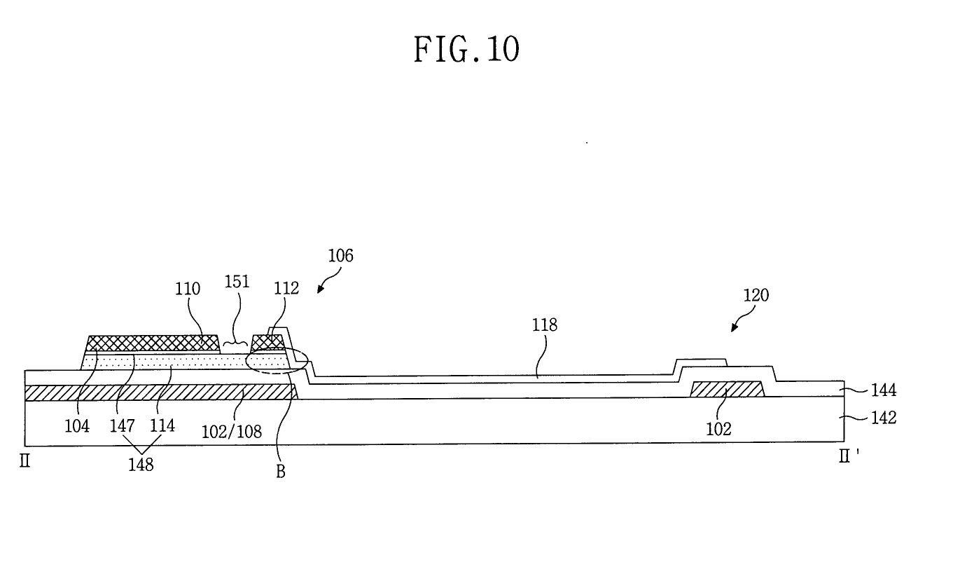

FIG. 10 is a planar schematic diagram illustrating a portion of a thin film transistor array substrate according to yet another embodiment of the invention. In FIG. 10, a thin film transistor array substrate includes a thin film transistor 106 and a pixel electrode 118 without an overlaying protective film. The pixel electrode 118 is formed is directly on a source electrode 112 of the thin film transistor 106 and a gate insulating film 144. Thus, a portion of the pixel electrode 118 covers the drain electrode 112. In addition, a storage capacitor 120 is formed by the overlapping of the pixel electrode 118 and the gate line 102 with only the gate insulating film 144 therebetween.

Further, an oxide film 153 is formed over a channel portion 151 of the thin film transistor 106. The oxide film 153 may include a silicon oxide film formed above or in an upper portion of the channel portion 151. For example, the oxide film 153 may be formed by oxidizing the upper portion of the channel portion 151 by exposing the upper portion to O₂ plasma. Thus, the process of forming a protective film overlaying the thin film transistor 106 and the pixel electrode 118 may be omitted. Further, a structure of the thin film transistor array substrate is simplified, thereby reducing fabricating cost. Accordingly, the most vulnerable channel portion 151 in the thin film transistor array substrate is protected from exposure, while simplifying the structure and the manufacturing method of the thin film transistor array substrate.

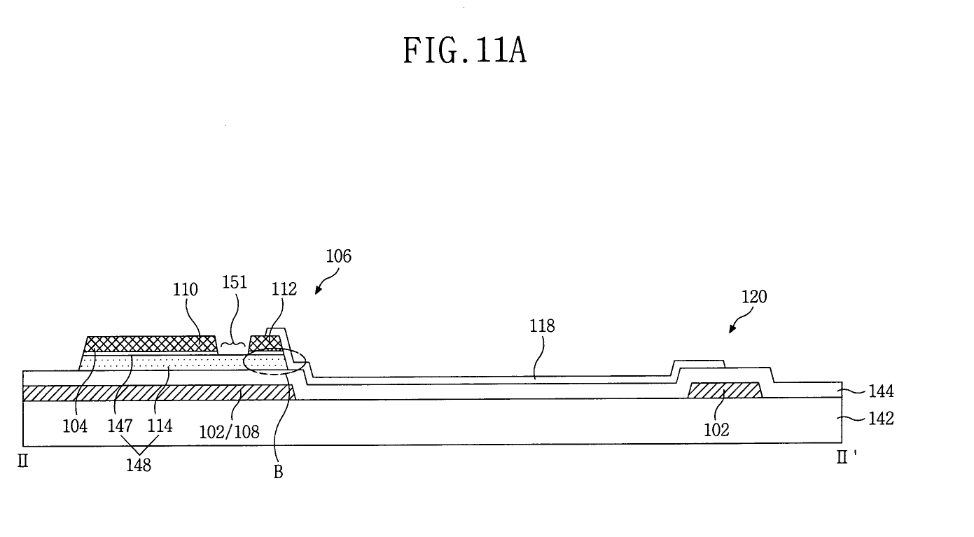

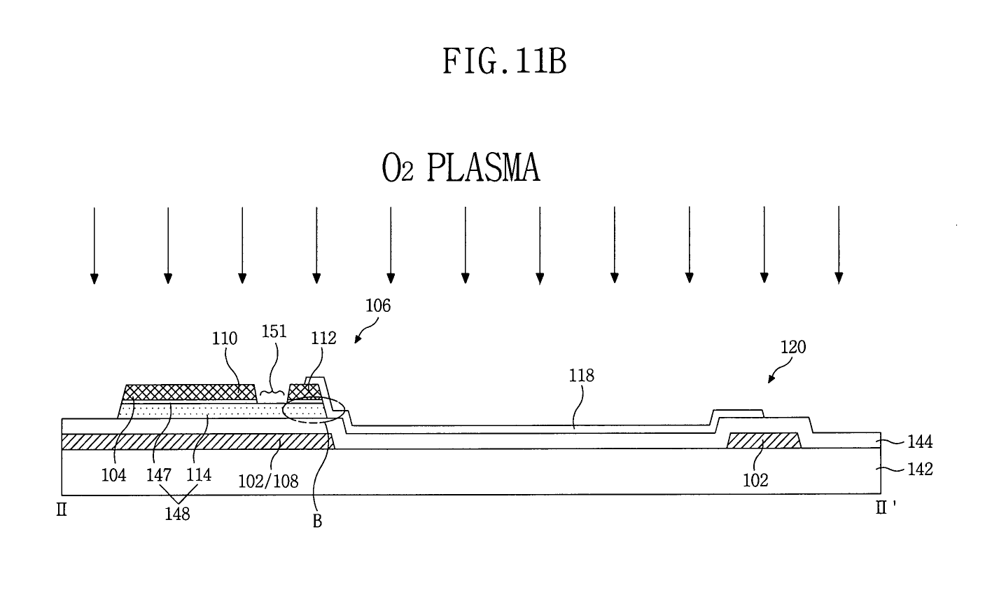

FIGS. 11A and 11B are sectional schematic diagrams illustrating a method of manufacturing a thin film transistor array substrate according to another embodiment of the invention. In FIG. 11A, a gate electrode 108, a gate line 102, a gate insulating film 144, a semiconductor pattern 148 and source/drain patterns including a data line 104, a source electrode 110, and a drain electrode 112 may be formed on a lower substrate 142 by a method similar to those shown in FIGS. 7A and 7B.

Then, a transparent electrode material is formed on the lower substrate 142 covering the gate insulating film 144 and the exposed region of a channel region 151 of a thin film transistor 106. The transparent electrode material subsequently is patterned by a photolithography and etching process using the mask to thereby form the pixel electrode 118. The pixel electrode 118 covers a region of the drain electrode 112.

As shown in FIG. 11B, the channel portion 151 of the thin film transistor is surface-processed by using O₂ plasma, to thereby form an oxide film of SiO₂ in an upper region of the channel portion 151.

As described above, the thin film transistor array substrate and the fabricating method thereof according to an embodiment of the invention form the semiconductor pattern positioned at the drain electrode and a lower portion of the drain electrode to be entirely overlapped the gate electrode. Accordingly, a backlight light is shielded by the gate electrode, and a backlight light is not incident on the semiconductor pattern at the lower portion of the drain electrode. As a result, an activation of the semiconductor pattern at a lower portion of the drain electrode is prevented and a leakage current is not generated. Thus, a deterioration of a display quality is prevented.

It will be apparent to those skilled in the art that various modifications and variations can be made in the thin film transistor array substrate and the manufacturing method thereof of embodiments of the invention without departing from the spirit or scope of the invention. Thus, it is intended that embodiments of the invention cover the modifications and variations of this invention provided they come within the scope of the appended claims and their equivalents.

What is claimed is:

1. A thin film transistor array substrate, comprising:
a gate line and a data line intersecting each other on a substrate with a gate insulating film therebetween;
a thin film transistor at an intersection of the gate line and the data line, the thin film transistor including a gate electrode electrically connected to the gate line, a semiconductor pattern overlapping the gate electrode with the gate insulating film therebetween, and a source electrode and a drain electrode above the semiconductor pattern; and
a pixel electrode contacting the drain electrode of the thin film transistor, the semiconductor pattern positioned at a lower portion of the drain electrode substantially completely overlapping at least one of the gate electrode and the gate line.

2. The thin film transistor array substrate as claimed in claim 1, wherein the drain electrode completely overlaps at least one of the gate electrode and the gate line.

3. The thin film transistor array substrate as claimed in claim 1, wherein the gate electrode is a non-protruding portion of the gate line.

4. The thin film transistor array substrate as claimed in claim 1, wherein the pixel electrode includes a protruding portion extending above the drain electrode and the gate line.

5. The thin film transistor array substrate as claimed in claim 1, wherein the source electrode is a protruding portion from the data line and entirely overlaps the gate line.

6. The thin film transistor array substrate as claimed in claim 1, further comprises:
a protective film on the pixel electrode and the thin film transistor, the protective film having a contact hole exposing a region of the drain electrode of the thin film transistor and the pixel electrode electrically contacting the drain electrode via the contact hole.

7. The thin film transistor array substrate as claimed in claim 6, wherein the protective film covers a channel region of the thin film transistor.

8. The thin film transistor array substrate as claimed in claim 1, wherein the thin film transistor includes:
a channel region between the source electrode and the drain electrode, and
an oxide film on an upper surface of the channel region.

9. The thin film transistor array substrate as claimed in claim 1, wherein a portion of the pixel electrode overlaps the gate line to form a storage capacitor with the gate insulating film and a protective film therebetween.

10. The thin film transistor array substrate as claimed in claim 1, wherein a portion of the pixel electrode overlaps the gate line to form a storage capacitor with only the gate insulating film therebetween.

11. A method of fabricating a thin film transistor array substrate, comprising:
forming a gate pattern on a substrate, the gate pattern including a gate line and a gate electrode electrically connected to the gate line;
forming a gate insulating film covering the gate pattern;
forming a semiconductor pattern and a source/drain pattern on the gate insulating film, the source/drain pattern including a data line intersecting the gate line, a source electrode electrically connected to the data line, and a drain electrode opposed to the source electrode; and
forming a pixel electrode contacted the drain electrode, the semiconductor pattern positioned at a lower portion of the drain electrode substantially completely overlapping at least one of the gate electrode and the gate line.

12. The method as claimed in claim 11, wherein the forming the gate pattern includes forming the gate electrode as a non-protruding portion of the gate line.

13. The method as claimed in claim 11, wherein the forming the pixel electrode includes forming a protruding portion extending above the drain electrode and the gate line.

14. The method as claimed in claim 11, wherein the forming the source/drain pattern includes forming the source electrode as a protruding portion from the data line, wherein the source electrode and the drain electrode are formed to entirely overlap the gate line.

15. The method as claimed in claim 11, further comprises:
forming a protective film on the gate insulating film, the semiconductor pattern and the source/drain pattern prior to forming the pixel electrode; and
forming a contact hole in the protective film, the contact hole exposing a region of the drain electrode, the pixel electrode electrically contacting the drain electrode via the contact hole.

16. The method as claimed in claim 11, further comprising:
forming an oxide film on an upper surface of a channel between the source electrode and the drain electrode.

17. The method as claimed in claim 16, wherein the forming the oxide film includes introducing O₂ plasma onto the substrate.

18. The method as claimed in claim 11, wherein the forming the pixel electrode includes forming a portion of the pixel electrode to overlap the gate line to form a storage capacitor with only the gate insulating film therebetween.

19. The method as claimed in claim 11, wherein the forming the pixel electrode includes forming a portion overlapping the gate line to form a storage capacitor with the gate insulating film and a protective film therebetween.

20. The method as claimed in claim 11, wherein the forming the source/drain pattern and the semiconductor pattern including a photolithography and etching process using a diffractive exposure mask.

21. A thin film transistor array substrate, comprising:
a gate line and a data line intersecting each other on a substrate;
a thin film transistor provided at each intersection between the data line and the gate line; and
a pixel electrode electrically connected to the thin film transistor, the thin film transistor being composed of the gate line, a source electrode electrically connected to the data line, a drain electrode opposed to the source electrode, and a semiconductor pattern, wherein the gate line shields light from being incident onto the semiconductor pattern.
